(19) United States
(12) Patent Application Publication
(10) Pub. No.: US 2025/0201559 A1
(43) Pub. Date: Jun. 19, 2025

(54) SEMICONDUCTOR PATTERN STRUCTURE PRESERVATION

(71) Applicant: International Business Machines Corporation, Armonk, NY (US)

(72) Inventors: Dario Goldfarb, Lake Carmel, NY (US); Karen Elizabeth Petrillo, Voorheesville, NY (US); Christopher M. Bottoms, Albany, NY (US); Yasiel Cabrera, Albany, NY (US); Zheng Guo Chen, Schenectady, NY (US); Nicholas Latham, Albany, NY (US)

(21) Appl. No.: 18/542,955

(22) Filed: Dec. 18, 2023

(51) Int. Cl. H01L 21/033; G03F 7/004; G03F 7/11; G03F 7/20; H01L 21/02; H01L 21/311

(52) U.S. Cl. CPC H01L 21/0337; H01L 21/0206; H01L 21/31138; G03F 7/0042; G03F 7/11; G03F 7/2004

(57) ABSTRACT

Techniques for semiconductor pattern structure preservation are provided. In one embodiment, the techniques include depositing a metal oxide resist layer over a substrate, removing a portion of the metal oxide resist layer to form a set of pattern structures over the substrate, where the set of pattern structures includes a first pattern structure and a second pattern structure, depositing a treatment composition over the set of pattern structures, where the treatment composition includes an organic liquid and a set of polymeric compounds, tethering a first polymeric compound of the set of polymeric compounds to at least one of: a top surface of a first pattern structure, or a side surface of the first pattern structure, and tethering a second polymeric compound of the set of polymeric compounds to at least one of: a top surface of a second pattern structure, or a side surface of the second pattern structure.

### BACKGROUND

The present disclosure relates to semiconductor pattern structure preservation, and more specifically, to preventing pattern collapse or distortion by tethering polymer chains to select photoresist materials.

High numerical aperture (NA) Extreme ultraviolet (EUV) lithography is a process that uses extreme ultraviolet light to create fine patterns on a silicon wafer. The short wavelength of EUV light enables the production of the patterns, which allows for the production of densely packed semiconductor devices. However, features of the patterns can collapse, or become distorted, during wet processing and subsequent drying processes, which can negatively impact performance of a resultant semiconductor device.

### SUMMARY

A method is provided according to one embodiment of the present disclosure. The method includes depositing a metal oxide resist layer over a substrate, removing a portion of the metal oxide resist layer to form a set of pattern structures over the substrate, where the set of pattern structures includes a first pattern structure and a second pattern structure, depositing a treatment composition over the set of pattern structures, where the treatment composition includes an organic liquid and a set of polymeric compounds, tethering a first polymeric compound of the set of polymeric compounds to at least one of: a top surface of a first pattern structure, or a side surface of the first pattern structure, and tethering a second polymeric compound of the set of polymeric compounds to at least one of: a top surface of a second pattern structure, or a side surface of the second pattern structure.

A semiconductor structure with a preserved pattern structure is provided according to one embodiment of the present disclosure. The semiconductor structure includes a substrate, a set of pattern structures disposed on the substrate, where the set of pattern structures is formed in a metal oxide resist layer, and where the set of pattern structures includes a first pattern structure and a second pattern structure, and a set of polymeric compounds tethered to the set of pattern structures, where a first polymeric compound of the set of polymeric compounds is tethered to at least one of: a top surface of a first pattern structure, or a side surface of the first pattern structure, and where a second polymeric compound of the set of polymeric compounds is tethered to at least one of: a top surface of a second pattern structure, or a side surface of the second pattern structure.

A treatment composition is provided according to one embodiment of the present disclosure. The treatment composition includes an organic liquid, and a polymeric compound that includes: a first class of side chains comprising a first set of functional groups, where the first set of functional groups can bind to a metal oxide surface, and a second class of side chains comprising a second set of functional groups, where the second set of functional groups can provide solubility of the polymeric compound in the organic liquid.

### BRIEF DESCRIPTION OF THE DRAWINGS

FIG. 1 illustrates a cross-sectional view of a wafer with a potential pattern distortion.

FIG. 2 illustrates a cross-sectional view of a semiconductor structure under fabrication, according to one embodiment.

FIG. 3 illustrates a cross-sectional view of a semiconductor structure under fabrication, according to one embodiment.

FIG. 4 illustrates a cross-sectional view of a semiconductor structure under fabrication, according to one embodiment.

FIGS. 5A-5C illustrate cross-sectional views of a semiconductor structure under fabrication, according to one embodiment.

FIG. 6 illustrates a cross-sectional view of a semiconductor structure under fabrication, according to one embodiment.

FIG. 7 illustrates a cross-sectional view of a semiconductor structure under fabrication, according to one embodiment.

FIG. 8 illustrates a cross-sectional view of a semiconductor structure under fabrication, according to one embodiment.

### DETAILED DESCRIPTION

A method is provided according to one embodiment of the present disclosure. The method includes depositing a metal oxide resist layer over a substrate, removing a portion of the metal oxide resist layer to form a set of pattern structures over the substrate, where the set of pattern structures includes a first pattern structure and a second pattern structure, depositing a treatment composition over the set of pattern structures, where the treatment composition includes an organic liquid and a set of polymeric compounds, tethering a first polymeric compound of the set of polymeric compounds to at least one of: a top surface of a first pattern structure, or a side surface of the first pattern structure, and tethering a second polymeric compound of the set of polymeric compounds to at least one of: a top surface of a second pattern structure, or a side surface of the second pattern structure. Advantageously, this enables prevention of a collapse or distortion of the set of pattern structures.

According to another embodiment of the present disclosure, the method further includes exposing the metal oxide resist layer to extreme ultraviolet radiation, and depositing a developing solution over the set of pattern structures. Further, according to another embodiment, the metal oxide resist layer includes negative tone photoresist material, and the organic liquid includes propylene glycol monomethyl ether acetate. Advantageously, this enables development of the set of pattern structures. This also aids in the deposition of the set of polymeric compounds on the set of pattern structures.

According to another embodiment of the present disclosure, the first polymeric compound includes a first class of side chains that include a first set of functional groups, where the first set of functional groups can bind to the first pattern structure or the second pattern structure, and a second class of side chains that include a second set of functional groups, where the second set of functional groups can provide solubility of the set of polymeric compounds in the organic liquid of the treatment composition. Further, according to another embodiment, the set of polymeric compounds includes polymethyl methacrylate-vinylphosphonic acid brushes, where the first class of side chains and the second class of side chains include vinylphosphonic acid branches, where the first set of functional groups includes a phosphonic acid functionality, and where the second set of functional groups includes an alkyloxy carbonyl functionality. Advantageously, this enables the set of polymer compounds to bind to metal oxide surfaces of the set of pattern structures, thereby preventing collapse or distortion of the set of pattern structures. This also allows the set of polymeric compounds to be dissolved or suspended in the organic liquid, thereby aiding in deposition of the set of polymeric compounds on the set of pattern structures.

According to another embodiment of the present disclosure, the set of polymeric compounds prevents a liquid from occupying a space between the side surface of the first pattern structure and the side surface of the second pattern structure. Advantageously, this enables prevention of a collapse or distortion of the set of pattern structures by preventing liquid from reaching surfaces of the set of pattern structures, thereby preventing capillary forces from collapsing or distorting the set of pattern structures.

According to another embodiment of the present disclosure, the set of pattern structures further includes a third pattern structure, where the third pattern structure is disposed on the substrate away from the first pattern structure or the second pattern structure, where a third polymeric compound of the set of polymeric compounds is tethered to at least one of: a top surface of the third pattern structure or a side surface of the third pattern structure, and where a liquid can occupy a space between a side surface of the third pattern structure and one of: the side surface of the first pattern structure or the side surface of the second pattern structure. Advantageously, this enables metrology processes to be performed on the third pattern structure.

According to another embodiment, tethering the first polymeric compound to the first pattern structure and tethering the second polymeric compound to the second pattern structure involve performing a physical adsorption process or a chemical adsorption process. Advantageously, this enables prevention of a collapse or distortion of the set of pattern structures.

According to another embodiment of the present disclosure, the method further includes removing the treatment composition from the first pattern structure via a spin-drying process, and heating the tethered first polymeric compound to a temperature of 110 degrees Celsius for up to 5 minutes. Further, according to another embodiment, the method further includes removing, via a rinsing process and a spin-drying process, a non-tethered polymeric compound from the set of pattern structures, where a rinse liquid applied during the rinsing process includes acetone. Advantageously, this enables control of a layer thickness or other sizing of the polymeric compound applied to the set of pattern structures.

According to another embodiment of the present disclosure, the method further includes removing, via a dry etching process, the first tethered polymeric compound from the first pattern structure, and removing, via the dry etching process, the second tethered polymeric compound from the second pattern structure. Advantageously, this enables use of a semiconductor structure without a collapsed or distorted pattern, and without tethered polymeric compounds.

A semiconductor structure with a preserved pattern structure is provided according to one embodiment of the present disclosure. The semiconductor structure includes a substrate, a set of pattern structures disposed on the substrate, where the set of pattern structures is formed in a metal oxide resist layer, and where the set of pattern structures includes a first pattern structure and a second pattern structure, and a set of polymeric compounds tethered to the set of pattern structures, where a first polymeric compound of the set of polymeric compounds is tethered to at least one of: a top surface of a first pattern structure, or a side surface of the first pattern structure, and where a second polymeric compound of the set of polymeric compounds is tethered to at least one of: a top surface of a second pattern structure, or a side surface of the second pattern structure.

According to another embodiment of the present disclosure, the first polymeric compound comprises: a first class of side chains that include a first set of functional groups, where the first set of functional groups can bind to the first pattern structure or the second pattern structure, and a second class of side chains that include a second set of functional groups, where the second set of functional groups can provide solubility of the set of polymeric compounds in an organic liquid. Further, according to another embodiment, the set of polymeric compounds includes polymethyl methacrylate-vinylphosphonic acid brushes, where the first class of side chains and the second class of side chains include vinylphosphonic acid branches, where the first set of functional groups includes a phosphonic acid functionality, and where the second set of functional groups includes an alkyloxy carbonyl functionality. Advantageously, this enables the set of polymer compounds to bind to metal oxide surfaces of the set of pattern structures, thereby preventing collapse or distortion of the set of pattern structures. This also allows the set of polymeric compounds to be dissolved or suspended in the organic liquid, thereby aiding in deposition of the set of polymeric compounds on the set of pattern structures.

According to another embodiment of the present disclosure, the set of polymeric compounds prevents a liquid from occupying a space between the side surface of the first pattern structure and the side surface of the second pattern structure. Advantageously, this enables prevention of a collapse or distortion of the set of pattern structures by preventing liquid from reaching surfaces of the set of pattern structures, thereby preventing capillary forces from collapsing or distorting the set of pattern structures.

According to another embodiment of the present disclosure, the set of pattern structures further includes a third pattern structure, where the third pattern structure is disposed on the substrate away from the first pattern structure or the second pattern structure, where a third polymeric compound of the set of polymeric compounds is tethered to at least one of: a top surface of the third pattern structure or a side surface of the third pattern structure, and where a liquid can occupy a space between a side surface of the third pattern structure and one of: the side surface of the first pattern structure or the side surface of the second pattern structure. Advantageously, this enables metrology processes to be performed on the third pattern structure.

According to another embodiment, tethering the first polymeric compound to the first pattern structure and tethering the second polymeric compound to the second pattern structure involve performing a physical adsorption process or a chemical adsorption process. Advantageously, this enables prevention of a collapse or distortion of the set of pattern structures.

A treatment composition is provided according to one embodiment of the present disclosure. The treatment composition includes an organic liquid, and a polymeric compound that includes: a first class of side chains comprising a first set of functional groups, where the first set of functional groups can bind to a metal oxide surface, and a second class of side chains comprising a second set of functional groups, where the second set of functional groups can provide solubility of the polymeric compound in the organic liquid. According to another embodiment of the present disclosure, the semiconductor structure further includes the organic liquid includes propylene glycol monomethyl ether acetate. Advantageously, this enables prevention of a collapse or distortion of the set of pattern structures.

Embodiments of the present disclosure improve upon semiconductor structure fabrication by providing semiconductor pattern structure preservation techniques. In one embodiment, a metal oxide resist layer is deposited over a substrate, a set of pattern structures are formed in the metal oxide resist layer, and a set of polymeric compounds are tethered to the set of pattern structures.

One benefit of the disclosed embodiments is to prevent a collapse or distortion of patterns formed on a semiconductor structure, thereby enabling further reduction in the dimensions of semiconductor devices. Further, embodiments of the present disclosure can improve the yield rate of semiconductor fabrication processes by preventing defects in the semiconductor structure due to distorted or collapsed patterns.

Descriptions of various embodiments of the present disclosure are presented for purposes of illustration, but are not intended to be exhaustive or limited to the embodiments disclosed. Modifications and variations can be made to embodiments of the present disclosure without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

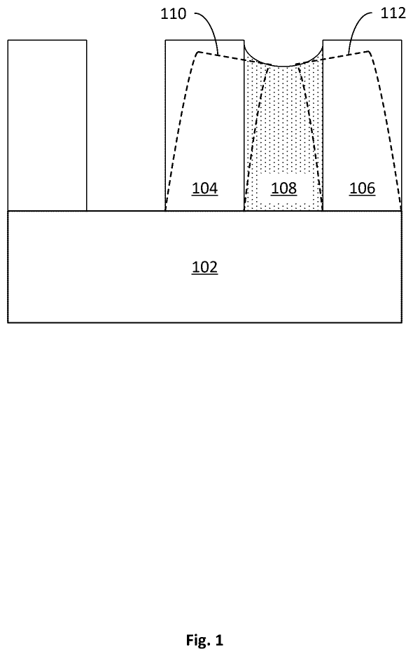

FIG. 1 illustrates a cross-sectional view of a wafer with a potential pattern distortion. In the illustrated embodiment, a photolithography process is performed to etch a pattern into a silicon substrate 102. Pillar 104 and pillar 106 of the etched pattern can be distorted, or may collapse, during further fabrication processes of the silicon substrate 102.

One cause of pattern collapse or distortion is due to capillary forces from liquid 108 deposited on the etched pattern via wet processing (e.g., development and rinsing) during semiconductor fabrication. As illustrated, the liquid 108 can cause capillary forces to act on pillar 110 (which can bend towards the liquid 108) and pillar 112 (which can bend towards the liquid 108). The distortion, and potential collapse, of the pattern can be exacerbated by pattern features such as pattern dimensions (e.g., a high height to width ratio of pillars of the pattern), the mechanical strength of the material into which the pattern is etched, semiconductor fabrication conditions, or the like.

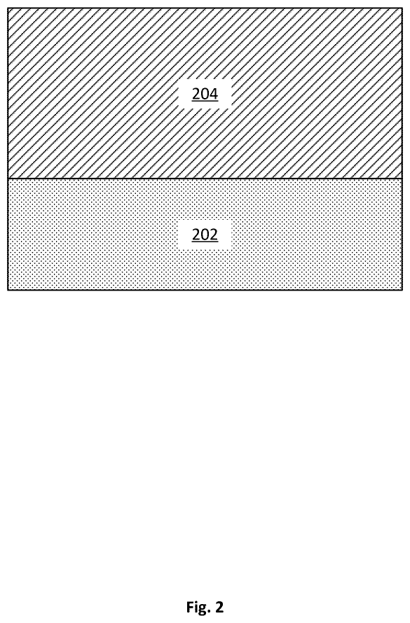

Techniques to prevent such pattern collapse or distortion in semiconductors are illustrated in FIGS. 2-8 below.

FIG. 2 illustrates a cross-sectional view of a semiconductor structure under fabrication, according to one embodiment. In the illustrated embodiment, a metal oxide resist layer 204 is deposited over a silicon substrate 202. In one embodiment, the metal oxide resist layer includes tin (Sn).

The metal oxide resist layer 204 can be a photoresist layer that includes metal oxide resist materials. In one embodiment, the metal oxide resist layer 204 is a negative tone photoresist layer. The metal oxide resist layer 204 can include negative tone photoresist materials such as metal organic frameworks (MOF), metal oxoclusters, metal cages, metal oxide nanoparticles, metal organic rings, or the like. In another embodiment, the metal oxide resist layer 204 is a positive tone resist layer.

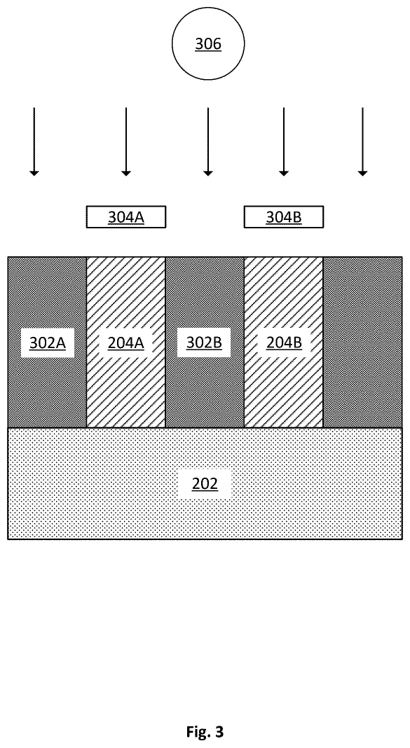

FIG. 3 illustrates a cross-sectional view of a semiconductor structure under fabrication, according to one embodiment. In the illustrated embodiment, portions of the metal oxide resist layer 204 are removed to form a set of pattern structures (e.g., a first pattern structure 302A and a second pattern structure 302B) of the semiconductor structure. In one embodiment, an extreme ultraviolet (EUV) radiation source 306 emits EUV radiation towards the semiconductor structure.

Photomasks 304A-304B can be positioned between the EUV radiation source 306 and the semiconductor structure to form the pattern in the metal oxide resist layer 204. In one embodiment, photomask 304A is positioned over a first portion 204A of the metal oxide resist layer 204, and photomask 304B is positioned over a second portion 204B of the metal oxide resist layer 204. In this manner, the first portion 204A and the second portion 204B of the metal oxide resist layer 204 are not exposed to the EUV radiation.

Portions of the metal oxide resist layer 204 that are exposed to the EUV radiation can become more resistant to developing solutions. A developing solution can include acetic acid (CH₃COOH), hydrochloric acid (HCl), or the like. In one embodiment, the developing solution is deposited over the metal oxide resist layer 204 to remove the first portion 204A and the second portion 204B (i.e., the unexposed portions of the metal oxide resist layer 204). As a result, trenches are formed in the semiconductor structure in the spaces formed by the removal of the first portion 204A and the removed second portions.

The remaining portions of the metal oxide resist layer 204 represent the pattern in the semiconductor structure. In one embodiment, the pattern includes the set of pattern structures (e.g., the first pattern structure 302A and the second pattern structure 302B).

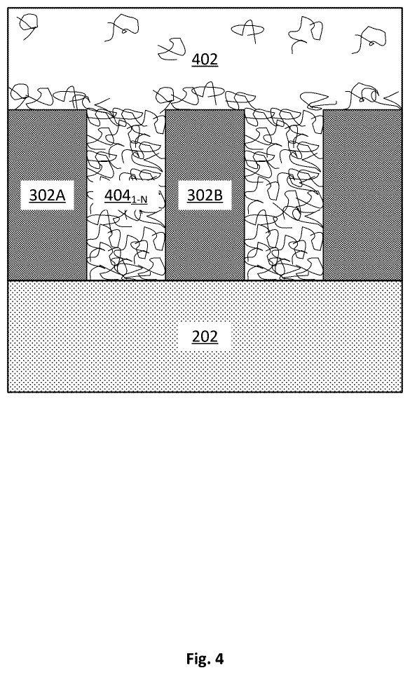

FIG. 4 illustrates a cross-sectional view of a semiconductor structure under fabrication, according to one embodiment. In the illustrated embodiment, a treatment composition 402 is deposited over the set of pattern structures.

The treatment composition 402 can include an organic liquid and a set of polymeric compounds 4041-N. In one embodiment, the organic liquid includes propylene glycol monomethyl ether acetate (PGMEA).

The set of polymeric compounds 4041-N can include polymethyl methacrylate (PMMA)-vinyl phosphonic acid (VPA) brushes suspended or dissolved in the organic liquid. The set of polymeric compounds 4041-N can be disposed on the silicon substrate 202, in the trenches between the first pattern structure 302A and the second pattern structure 302B, and on side surfaces or top surfaces of the set of pattern structures.

In one embodiment, the set of polymeric compounds 4041-N are tethered to the side surfaces and top surfaces of the set of pattern structures via a physical adsorption process or a chemical adsorption process. As used herein, “tether” may reference grafting a polymeric compound onto, from, or through a surface of the first pattern structure 302A or the second pattern structure 302B. In one embodiment, the polymeric compound is not tethered to the silicon substrate 202.

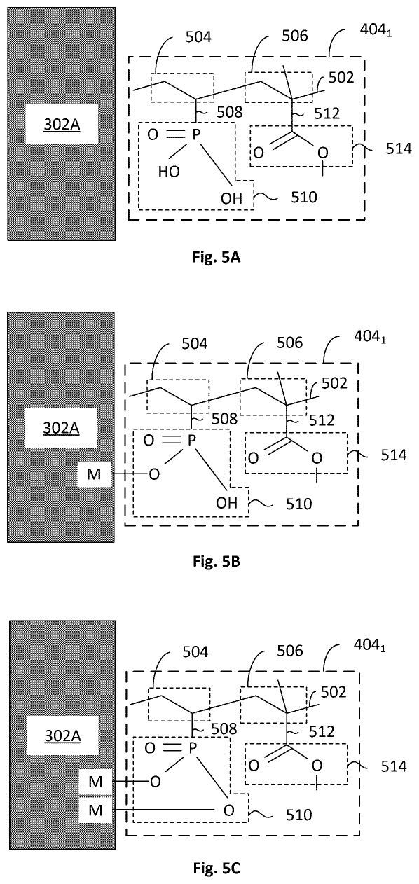

FIGS. 5A-5C illustrate cross-sectional views of a semiconductor structure under fabrication, according to one embodiment. FIG. 5A illustrates a first polymeric compound 4041 disposed on a surface of the first pattern structure 302A. The first polymeric compound 4041 can include a main chain 502, a first repeating monomer site 504, a second repeating monomer site 506, a first class of side chains 508, a first functional group 510, a second class of side chains 512, and a second functional group 514.

In one embodiment, the main chain 502 represents PMMA. The first repeating monomer site 504 and the second repeating monomer site 506 can represent connection points of methyl methacrylate (MMA) monomers or VPA monomers. The first class of side chains 508 and the second class of side chains 512 can represent VPA branches of the first polymeric compound 4041. The first functional group 510 can represent a phosphonic acid functionality. The second functional group 514 can represent an alkyloxy carbonyl functionality that provides solubility of the set of polymeric compounds 4041-N in the organic liquid of the treatment composition 402.

FIG. 5B illustrates the first polymeric compound 4041 being tethered to a metal oxide surface of the first pattern structure 302A. In one embodiment, a first metal atom of the metal oxide surface is bonded to an oxygen atom of a first hydroxyl group of the first functional group 510.

FIG. 5C illustrates the first polymeric compound 4041 being tethered to a metal oxide surface of the first pattern structure 302A. In one embodiment, a second metal atom of the metal oxide surface is bonded to an oxygen atom of a second hydroxyl group of the first functional group 510.

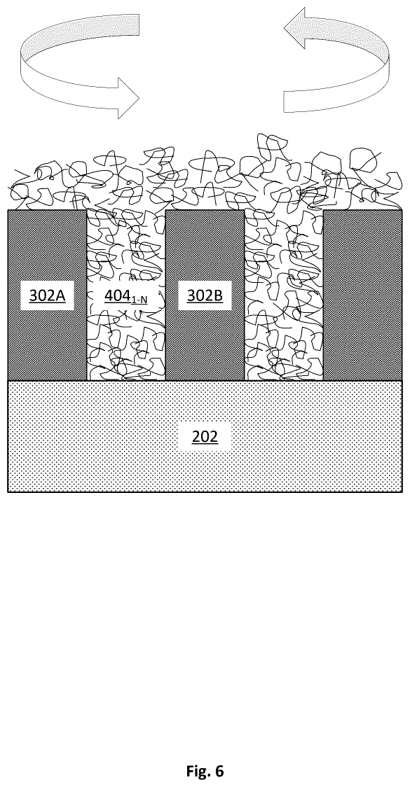

FIG. 6 illustrates a cross-sectional view of a semiconductor structure under fabrication, according to one embodiment. In the illustrated embodiment, an optional spin-drying process and baking process can be performed on the semiconductor structure.

In one embodiment, the semiconductor structure is spun at a rate of 1000 rpm to remove excess treatment composition. The semiconductor structure can then be baked at a temperature of 110 degrees (Celsius) for up to 5 minutes.

In one embodiment, the spin-drying process and baking process are used to control a layer thickness or other sizing of the polymeric compounds applied to the set of pattern structures. For instance, the processes can be performed to reduce a layer thickness of the polymeric compounds, such that the layer of polymeric compounds match a space between the first pattern structure 302A and the second pattern structure 302B.

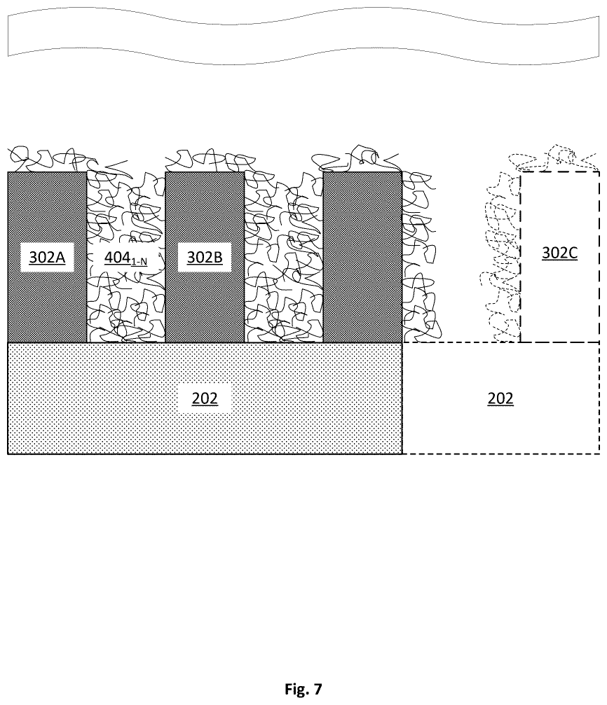

FIG. 7 illustrates a cross-sectional view of a semiconductor structure under fabrication, according to one embodiment. In the illustrated embodiment, a rinsing process can be performed to remove non-tethered polymeric compounds from the set of pattern structures (e.g., a first pattern structure 302A and a second pattern structure 302B). In one embodiment, a rinse liquid applied in during the rinsing process includes acetone.

After the rinsing process is performed, polymeric compounds remain tethered to top surfaces of the set of pattern structures, such that subsequent wet processes do not affect a height of the set of pattern structures. Further, polymeric compounds remain tethered to side surfaces of the set of pattern structures, such that the polymeric compounds can prevent liquid from occupying a space between the side surface of the first pattern structure 302A and the side surface of the second pattern structure 302B. In this manner, capillary forces do not cause a collapse or distortion of the set of pattern structures.

In one embodiment, the set of pattern structures includes a third pattern structure 302C formed on the silicon substrate 202 away from the first pattern structure 302A or the second pattern structure 302B. Polymeric compounds can be tethered to a top surface and a side surface of the third pattern structure 302C, such that a liquid can occupy a space between the side surface of the third pattern structure 302C and a side surface of the first pattern structure 302A or the second pattern structure 302B (since the polymeric compounds are not tethered to the silicon substrate 202). In this manner, metrology procedures may be performed on the third pattern structure 302C since the semiconductor structure is not fully covered by polymeric compounds.

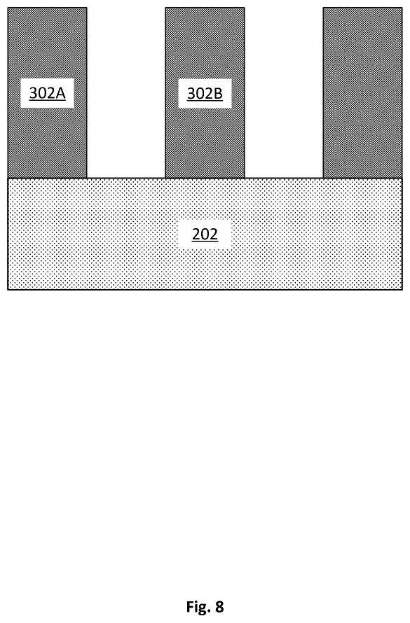

FIG. 8 illustrates a cross-sectional view of a semiconductor structure under fabrication, according to one embodiment. After the wet processing has been performed (i.e., when liquids will not be applied to the semiconductor structure further during fabrication), the tethered polymeric compounds are not needed to prevent pattern collapse or distortion due to capillary forces. Hence, a dry etching process can be performed to remove the polymeric compounds tethered to the set of pattern structures.

In the illustrated embodiment, the semiconductor structure includes a pattern without collapsed or distorted pattern structures. Further, the semiconductor structure does not include polymeric compounds.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

Embodiments of the present disclosure may reference an interlayer dielectric (ILD) material. The ILD material can be an insulating material used to electrically isolate different layers of a semiconductor structure. The ILD material can be SiO2, SiN, a low-k dielectric material, or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Ultra-low-k dielectric materials can include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process. In the templated process, a precursor typically contains a composite of thermally labile and stable materials. After film deposition, the thermally labile materials can be removed by thermal heating, leaving pores in the dielectric film. In the sol gel process, porous low-k dielectric films can be formed by hydrolysis and polycondensation of an alkoxide(s) such as tetraetehoxysilane (TEOS).

Embodiments of the present disclosure may reference p-type or n-type semiconductor structures. “P-type” can refer to the addition of impurities to an intrinsic semiconductor that creates deficiencies of valence electrons. In a silicon-containing substrate, examples of p-type dopants (i.e., impurities) include, but are not limited to, boron, aluminum, gallium, and indium. “N-type” can refer to the addition of impurities that contributes free electrons to an intrinsic semiconductor. In a silicon containing substrate examples of n-type dopants (i.e., impurities) include, but are not limited to, antimony, arsenic and phosphorous.

Various processes used to form a semiconductor structure that will be packaged into an IC fall into four general categories: film deposition, removal/etching, semiconductor doping and patterning/lithography. Deposition is any process that grows, coats, or otherwise transfers a material onto the wafer. Examples of such technologies include physical vapor deposition (PVD), chemical vapor deposition (CVD), plasma enhanced chemical vapor deposition (PECVD), electrochemical deposition (ECD), atomic layer deposition (ALD), epitaxial growth/deposition, or the like. The term “epitaxial growth/deposition” may reference growth of a first semiconductor material on a surface of a second semiconductor material, in which the first semiconductor material has the same crystalline characteristics as the surface of the second semiconductor material. In an epitaxial growth process, chemical reactants provided by source gases are controlled, and system parameters are set so that deposited atoms are disposed on the surface of the second semiconductor material with sufficient energy to traverse the surface and orient to a crystal arrangement of atoms of the surface. Examples of epitaxial growth/deposition process techniques include rapid thermal chemical vapor deposition (RTCVD), low-energy plasma deposition (LEPD), ultra-high vacuum chemical vapor deposition (UHVCVD), atmospheric pressure chemical vapor deposition (APCVD), molecular beam epitaxy (MBE), or the like.

Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, transistors can be built and wired together to form the circuitry of a modern semiconductor device.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation, or the like. Afterwards, the exposed photoresist is developed utilizing a conventional resist development process.

Following the development step, the etching step can be performed to transfer the pattern from the patterned photoresist into the interlayer dielectric. The etching step used in forming the at least one opening can include a dry-etching process (e.g., reactive ion etching, ion beam etching, plasma etching, or laser ablation), a wet chemical etching process, or any combination thereof.

While the foregoing is directed to embodiments of the present disclosure, other and further embodiments of the present disclosure may be devised without departing from the basic scope thereof, and the scope thereof is determined by the claims that follow.

1. A method, comprising:
depositing a metal oxide resist layer over a substrate;
removing a portion of the metal oxide resist layer to form a set of pattern structures over the substrate, wherein the set of pattern structures includes a first pattern structure and a second pattern structure;
depositing a treatment composition over the set of pattern structures, wherein the treatment composition includes an organic liquid and a set of polymeric compounds;
tethering a first polymeric compound of the set of polymeric compounds to at least one of: a top surface of a first pattern structure, or a side surface of the first pattern structure; and
tethering a second polymeric compound of the set of polymeric compounds to at least one of: a top surface of a second pattern structure, or a side surface of the second pattern structure.

2. The method of claim 1, wherein removing the portion of the metal oxide resist layer involves:
exposing the metal oxide resist layer to extreme ultraviolet radiation; and
depositing a developing solution over the set of pattern structures.

3. The method of claim 1, wherein the first polymeric compound comprises:
a first class of side chains that include a first set of functional groups, wherein the first set of functional groups can bind to the first pattern structure or the second pattern structure; and
a second class of side chains that include a second set of functional groups, wherein the second set of functional groups can provide solubility of the set of polymeric compounds in the organic liquid of the treatment composition.

4. The method of claim 3, wherein the set of polymeric compounds includes polymethyl methacrylate-vinylphosphonic acid brushes;
wherein the first class of side chains and the second class of side chains include vinylphosphonic acid branches;
wherein the first set of functional groups includes a phosphonic acid functionality; and
wherein the second set of functional groups includes an alkyloxy carbonyl functionality.

5. The method of claim 1, wherein the set of polymeric compounds prevents a liquid from occupying a space between the side surface of the first pattern structure and the side surface of the second pattern structure.

6. The method of claim 1, wherein the set of pattern structures further includes a third pattern structure, wherein the third pattern structure is disposed on the substrate away from the first pattern structure or the second pattern structure, wherein a third polymeric compound of the set of polymeric compounds is tethered to at least one of: a top surface of the third pattern structure or a side surface of the third pattern structure, and wherein a liquid can occupy a space between a side surface of the third pattern structure and one of: the side surface of the first pattern structure or the side surface of the second pattern structure.

7. The method of claim 1, wherein tethering the first polymeric compound to the first pattern structure and tethering the second polymeric compound to the second pattern structure involve performing a physical adsorption process or a chemical adsorption process.

8. The method of claim 1, further comprising:
removing the treatment composition from the first pattern structure via a spin-drying process; and
heating the tethered first polymeric compound to a temperature of 110 degrees Celsius for up to 5 minutes.

9. The method of claim 1, further comprising:
removing, via a rinsing process and a spin-drying process, a non-tethered polymeric compound from the set of pattern structures, wherein a rinse liquid applied during the rinsing process includes acetone.

10. The method of claim 1, further comprising:
removing, via a dry etching process, the first tethered polymeric compound from the first pattern structure; and
removing, via the dry etching process, the second tethered polymeric compound from the second pattern structure.

11. The method of claim 1, wherein the metal oxide resist layer includes negative tone photoresist material; and
wherein the organic liquid includes propylene glycol monomethyl ether acetate.

12. A semiconductor structure comprising:
a substrate;
a set of pattern structures disposed on the substrate, wherein the set of pattern structures is formed in a metal oxide resist layer, and wherein the set of pattern structures includes a first pattern structure and a second pattern structure; and
a set of polymeric compounds tethered to the set of pattern structures, wherein a first polymeric compound of the set of polymeric compounds is tethered to at least one of: a top surface of a first pattern structure, or a side surface of the first pattern structure, and wherein a second polymeric compound of the set of polymeric compounds is tethered to at least one of: a top surface of a second pattern structure, or a side surface of the second pattern structure.

13. The semiconductor structure of claim 12, wherein the first polymeric compound comprises:
a first class of side chains that include a first set of functional groups, wherein the first set of functional groups can bind to the first pattern structure or the second pattern structure; and
a second class of side chains that include a second set of functional groups, wherein the second set of functional groups can provide solubility of the set of polymeric compounds in an organic liquid.

14. The semiconductor structure of claim 13, wherein the set of polymeric compounds include polymethyl methacrylate-vinylphosphonic acid brushes;
wherein the first class of side chains and the second class of side chains include vinylphosphonic acid branches;
wherein the first set of functional groups includes a phosphonic acid functionality; and
wherein the second set of functional groups includes an alkyloxy carbonyl functionality.

15. The semiconductor structure of claim 12, wherein the set of polymeric compounds prevents a liquid from occupying a space between the side surface of the first pattern structure and the side surface of the second pattern structure.

16. The semiconductor structure of claim 12, wherein the set of pattern structures further includes a third pattern structure, wherein the third pattern structure is disposed on the substrate away from the first pattern structure or the second pattern structure, wherein a third polymeric compound of the set of polymeric compounds is tethered to at least one of: a top surface of the third pattern structure or a side surface of the third pattern structure, and wherein a liquid can occupy a space between a side surface of the third pattern structure and one of: the side surface of the first pattern structure or the side surface of the second pattern structure.

17. The semiconductor structure of claim 12, wherein tethering the set of polymeric compounds to the set of pattern structures involves performing a physical adsorption process or a chemical adsorption process.

18. The semiconductor structure of claim 12, wherein the metal oxide resist layer includes negative tone photoresist material.

19. A treatment composition, comprising:
an organic liquid; and
a polymeric compound that includes: a first class of side chains comprising a first set of functional groups, wherein the first set of functional groups can bind to a metal oxide surface, and a second class of side chains comprising a second set of functional groups, wherein the second set of functional groups can provide solubility of the polymeric compound in the organic liquid.

20. The treatment composition of claim 19, wherein the organic liquid includes propylene glycol monomethyl ether acetate.
